(19) United States
(12) Patent Application Publication
(10) Pub. No.: US 2006/0107180 A1
(43) Pub. Date: May 18, 2006

(54) Apparatus and method for constructing low-density parity check matrix

(75) Inventors: Hyun-jung Kim, Suwon-si (KR); Yoon-woo Lee, Suwon-si (KR)

Correspondence Address: STEIN, MCEWEN & BUI, LLP, 1400 EYE STREET, NW, SUITE 300, WASHINGTON, DC, 20005, US

(73) Assignee: Samsung Electronics Co., Ltd., Suwon-si (KR)

(21) Appl. No.: 11/213,994

(22) Filed: Aug. 30, 2005

(30) Foreign Application Priority Data
Oct. 13, 2004 (KR) 2004-81779

(51) Int. Cl. H03M 13/00

(52) U.S. Cl. 714/758

(57) ABSTRACT

An apparatus and method for constructing a low density parity check matrix. A p-th positive-shift block is generated by shifting all elements of an identity matrix p times to the right; a p-th negative-shift block is generated by shifting all elements of the identity matrix p times to the left; and one or more pairs of different p-th positive- and negative-shift blocks symmetrically arranged in the vertical direction are horizontally arranged.

### CROSS REFERENCE TO RELATED APPLICATIONS

This application claims the benefit of Korean Patent Application No. 2004-81779, filed on Oct. 13, 2004, in the Korean Intellectual Property Office, the disclosure of which is incorporated herein reference.

### BACKGROUND OF THE INVENTION

1. Field of the Invention

Aspects of the present invention relate to an apparatus for and a method of constructing a parity check matrix, and more particularly, to an apparatus for and a method of easily constructing a low-density parity check matrix, while avoiding a cycle-4 phenomenon.

2. Description of the Related Art

FIG. 1A shows matrices for explaining a concept of low-density parity check (LDPC) coding and decoding. Among methods of generating parity information for error correction, a low-density parity check coding method is commonly used. The low-density parity check coding method generates parity information by using a low-density parity check matrix H having elements which are mostly 0's along with some “1”s.

In the parity check matrix, the number of “1”s in each row or column is referred to as row degree or column degree, respectively. A parity check matrix where all columns have the same column degree and where all rows have the same row degree is called a regular parity check matrix. A parity check matrix where all rows and columns do not have the same row degree and column degree is called an irregular parity check matrix. In a regular parity check matrix, the row degree is referred to as row weight, Wr, and the column degree is referred to as column weight, Wc.

Parity information is generated on the basis of LDPC coding using Equation (1):
HX=0 (1)

Here, H is an m×n parity check matrix, and X is an n×1 codeword matrix. X is comprised of m message information and p parity information, so that m+p=n.

A basic concept of LDPC coding is taught by D. J. MacKay, “Good Error-correction Codes Based on Very Sparse Matrices”, IEEE Trans. on Information Theory, vol. 45, no. 2, pp. 399-431, 1999. D. J. Mackay teaches that parity information is generated by solving Equation (1) with matrix algebra, such as a Gaussian elimination method.

Parity check decoding also includes a procedure for performing a parity check on the basis of Equation (1).

There are basically two different methods of constructing a conventional parity check matrix of LDPC codes. In the first method, row indexes which indicate row positions of each “1” in each column of the parity check matrix H are arbitrarily set by a user. For example, row indexes of 1, 3, and 5 may be set for the first column, row indexes of 2, 4, and 6 may be set for the second column, 7, 9, and 11 may be set for the third column, and so forth. This method can be easily implemented, but has poor bit error rate (BER) performance. In the second method, row indexes which indicate row positions of “1” in each column of the parity check matrix H are determined randomly. Implementation of the second method is more complicated since row positions (indexes) of “1”s are randomly distributed. However, the second method has excellent BER performance.

An example of the second method of constructing the parity check matrix will now be described. First, Wc row indexes of “1”s in the first column are determined. Next, arbitrary row indexes of “1”s in the second column are determined such that none are the same as row indexes of “1”s in the first column. Then, arbitrary row indexes of “1”s for the third column are determined such that none are the same as row indexes of “1”s in the first and second columns.

This procedure is repeated through to the last column.

In summary, in the second conventional method of constructing a parity check matrix, row indexes of “1”s in each column of the parity check matrix H are set arbitrarily as long as no two columns have the same row index.

No matter which of the two methods is applied, positions of “1”s of the parity check matrix should be set not to trigger a cycle-4 phenomenon that degrades BER performance in decoding when element “1”s are set in special positions of the parity check matrix. Here, the special positions are four corners of any rectangle in the parity check matrix, for example, (2, 2), (2, 8), (4, 8), and (4, 2), which form a rectangle when connected to each other.

FIG. 1B shows an exemplary parity check matrix that may trigger the cycle-4 phenomenon. In FIG. 1B, “1”s are set in the four corners of a rectangle.

At present, no common algorithm (or method) is known to avoid the cycle-4 phenomenon. Using conventional methods, “1”'s should be cautiously set to avoid the cycle-4 phenomenon when constructing a low-density parity check matrix, which is considerably inconvenient.

In addition, a large memory space is needed to store row indexes of “1” of a parity check matrix because the parity check matrix generally has considerable dimensions.

### SUMMARY OF THE INVENTION

Aspects of the present invention provide a method of more simply constructing a parity check matrix while preventing a cycle-4 phenomenon. Further, aspects of the present invention provide an apparatus for and a method of constructing a parity check matrix, which reduces a memory space required for the parity check matrix.

According to an aspect of the present invention, there is provided a method of constructing a low-density parity check matrix, the method comprising: generating a p-th positive-shift block by shifting all elements of an identity matrix p times to the right; generating a p-th negative-shift block by shifting all elements of the identity matrix p times to the left; and horizontally arranging one or more pairs of different p-th positive- and negative-shift blocks symmetrically arranged in the vertical direction.

According to an aspect of the present invention, the horizontally arranging of the one or more pairs of p-th positive- and negative-shift blocks comprises: placing the p-th negative-shift block directly above or directly below the p-th positive-shift block.

According to an aspect of the present invention, the horizontally arranging of the one or more pairs of p-th positive- and negative-shift blocks comprises: sequentially arranging the positive- and negative-shift blocks by their shift numbers.

According to an aspect of the present invention, the method of constructing a low-density parity check matrix further comprises: alternately arranging identity matrices and zero matrices, directly above or directly below an upper sub-matrix resulting from symmetrically arranging the positive- and negative-shift blocks in the vertical direction.

According to an aspect of the present invention, the alternately arranging of the identity matrices and the zero matrices directly above or directly below an upper sub-matrix comprises: generating a lower sub-matrix by alternately arranging the identity and zero matrices in both vertical and horizontal directions, where the identity and zero matrices have the same dimensions as the positive- and negative-shift blocks; and placing the lower sub-matrix directly above or directly below the upper sub-matrix.

According to an aspect of the present invention, the method of constructing a low-density parity check matrix further comprises: generating a regular parity check matrix by alternately arranging the upper sub-matrices and lower sub-matrices.

According to an aspect of the present invention, the generating of a regular parity check matrix comprises: generating a first sub matrix by placing the lower sub-matrix directly below the upper sub-matrix; generating a second sub matrix by placing the upper sub-matrix directly below the lower sub-matrix; and placing the second sub matrix on the left or right of the first sub matrix.

According to another aspect of the present invention, there is provided an apparatus for constructing a low-density parity check matrix, the apparatus comprising: a positive-shift block generator that generates a p-th positive-shift block by shifting all elements of an identity matrix p times to the right; a negative-shift block generator that generates a p-th negative-shift block by shifting all elements of the unit matrix p times to the left; and an upper sub-matrix generator that generates an upper sub-matrix by horizontally arranging one or more pairs of different p-th positive- and negative-shift blocks symmetrically arranged in the vertical direction.

According to an aspect of the present invention, the upper sub-matrix generator generates the upper sub-matrix by placing the p-th negative-shift block directly above or directly below the p-th positive-shift block.

According to an aspect of the present invention, the upper sub-matrix generator generates the upper sub-matrix by sequentially arranging positive- and negative-shift blocks by their shift numbers.

According to an aspect of the present invention, the apparatus for constructing a low-density parity check matrix further comprises: a lower sub-matrix generator that generates a lower sub-matrix by alternately arranging identity matrices and zero matrices that each have the same dimensions as the positive- and negative-shift blocks, and the lower sub-matrix having the same dimensions of the upper sub-matrix; and a first sub-matrix generator that generates a first sub-matrix by placing the lower sub-matrix directly below the upper sub-matrix.

According to an aspect of the present invention, the apparatus for constructing a low-density parity check matrix further comprises: a second sub-matrix generator that generates a second sub-matrix by placing the lower sub-matrix directly above the upper sub-matrix; a parity check matrix generator that generates a regular parity check matrix by symmetrically arranging the first sub-matrix and the second sub-matrix in the horizontal direction.

According to another aspect of the present invention, there is provided a computer-readable recording medium storing a program for a computer to execute the method described above.

Additional aspects and/or advantages of the invention will be set forth in part in the description which follows and, in part, will be obvious from the description, or may be learned by practice of the invention.

### BRIEF DESCRIPTION OF THE DRAWINGS

These and/or other aspects and/or advantages of the invention will become apparent and more readily appreciated from the following description of the embodiments, taken in conjunction with the accompanying drawings of which:

FIG. 1A shows matrices for explaining a concept of low-density parity check coding and decoding;

FIG. 1B is an exemplary parity check matrix that may trigger a cycle-4 phenomenon;

FIG. 2 is a parity check matrix generated by a first embodiment of the present invention;

FIG. 3 shows some components of the parity check matrix of FIG. 2 for explaining how a cycle-4 phenomenon is avoidable;

FIG. 4 is a flowchart illustrating a method of constructing the parity check matrix of FIG. 2.

FIG. 5 shows a parity check matrix generated by a second embodiment of the present invention;

FIG. 6 shows a parity check matrix generated by a third embodiment of the present invention;

FIG. 7 shows some components of the parity check matrix of FIG. 6 for explaining how a cycle-4 phenomenon is avoidable;

FIG. 8 is a flowchart illustrating a method of constructing the parity check matrix of FIG. 6;

FIG. 9 shows a procedure for generating a parity check matrix according to a fourth embodiment of the present invention;

FIG. 10 is flowchart illustrating a method of constructing the resulting parity check matrix of FIG. 9; and

FIG. 11 is a block diagram of an apparatus for constructing a parity check matrix, according to an embodiment of the present invention.

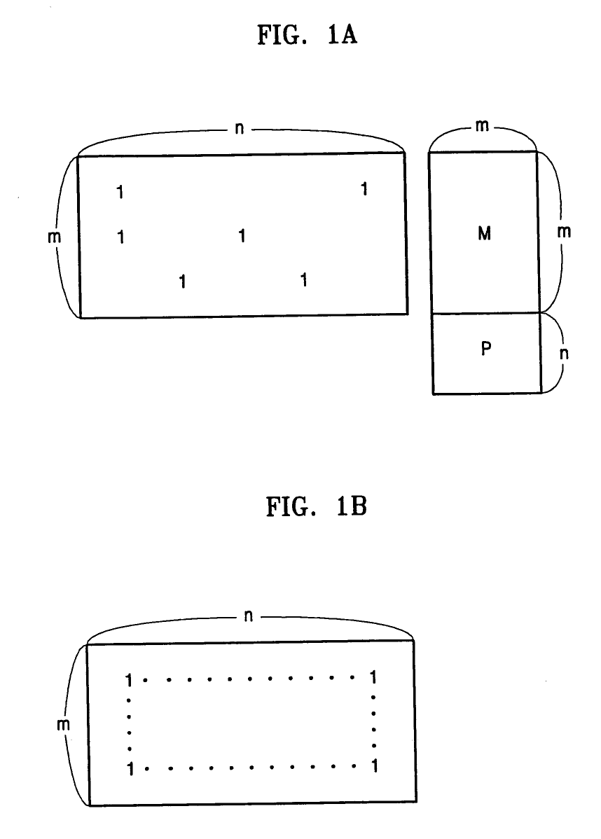

### DETAILED DESCRIPTION OF THE INVENTION

Reference will now be made in detail to the present embodiments of the present invention, examples of which are illustrated in the accompanying drawings, wherein like reference numerals refer to the like elements throughout. The embodiments are described below in order to explain the present invention by referring to the figures.

In all embodiments of the present invention, a parity check matrix includes one or more shift blocks. The shift blocks are categorized into positive-shift blocks and negative-shift blocks. A p-th positive-shift block is a matrix generated by shifting all elements of an identity matrix p times to the right. A p-th negative-shift block is a matrix generated by shifting all elements of the identity matrix p times to the left.

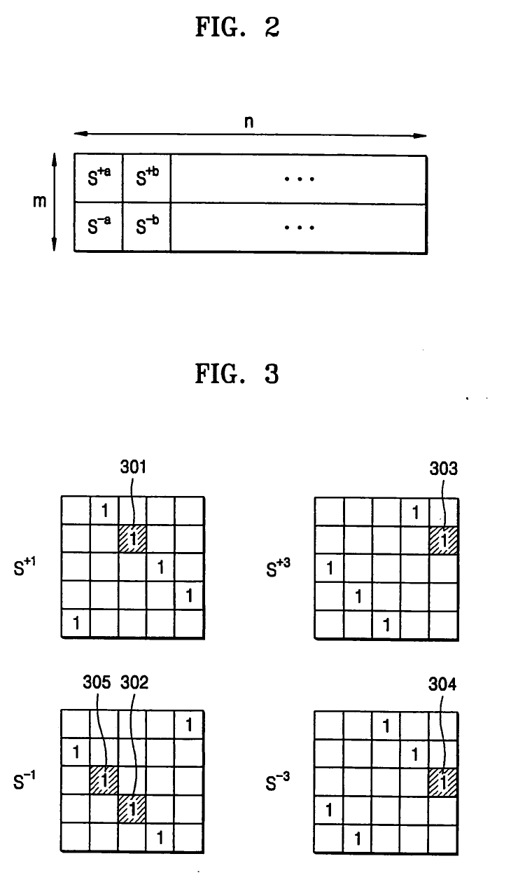

FIG. 2 shows a parity check matrix generated by a first embodiment of the present invention. In the first embodiment of the present invention, the p-th positive- and negative-shift blocks are symmetrically placed on upper and lower halves of the parity check matrix. If the p-th positive-shift block is placed on the upper half of the parity check matrix, the p-th negative-shift block is placed on the lower half of the parity check matrix symmetrically below the p-th positive-shift block. If the p-th negative-shift block is placed on the upper half of the parity check matrix, the p-th positive-shift block is placed directly below the p-th negative-shift block. No two p-th positive or negative blocks appear in the parity check matrix.

In order to prevent a cycle-4 phenomenon, there are two rules in constructing the parity check matrix according to aspects of the present invention, as follows:

Rule 1: the p-th positive-shift block and the p-th negative-shift block are symmetrically arranged in the vertical direction; and

Rule 2: no two p-th positive- or p-th negative shift blocks appear in the horizontal direction.

Dimensions of a sub-block, a constituent block of an m×n parity check matrix are m/2×m/2. Therefore, n=m/2×N, and the number of sub-blocks required to form the m×n parity check matrix is 2N, that is, N for positive-shift blocks and N for negative-shift blocks.

The parity check matrix shown in FIG. 2 requires a smaller memory space for storage, since instead of storing row indexes of each “1” in each column of the parity check matrix as in conventional methods, only shift numbers, p, of positive, or negative-shift blocks need to be stored. For example, in the embodiment of FIG. 2, storing only shift numbers of the parity check matrix, such as, a, b, . . . , etc. (from the left) enables the parity check matrix to be re-constructed. The internal structure of the positive- or negative-shift block is specified by the shift number of the parity check matrix, since the parity check matrix can be specified by an arrangement order of shift numbers.

A p-th positive-shift block and a p-th negative-shift block will now be denoted by S^{+p} and S^{-p}, respectively.

FIG. 3 shows a detailed parity check matrix for explaining how the cycle-4 phenomenon is avoided in the parity check matrix of FIG. 2. Referring to FIG. 3, the parity check matrix includes 4 shift blocks, S⁺¹, S⁻¹, S⁺³ and S⁻³.

There is a first occasion where two positions are chosen as two corners of a rectangle on the upper part of the parity check matrix that includes shift blocks S⁺¹, S⁺², S⁺³, . . . , and then another two positions are chosen as the remaining corners of the rectangle on the lower part of the parity check matrix that includes shift blocks S⁻¹, S⁻², S⁻³, . . . . Here, when connected, the 4 corners constitute the rectangle having corner positions which are associated with the cycle-4 phenomenon.

Since any given row or column of an identity matrix has only a single “1”, and a shift block is a matrix generated by shifting all elements of an identity matrix to the left or right, row weight, the number of “1”s in all the rows of the shift block, and column weight, the number of “1”s in all the columns of the shift block are all 1. Therefore, any given row or column of a shift block has only a single “1”. In the parity check matrix according to embodiments of the present invention, the p-th positive-shift block is placed directly above or directly below the corresponding negative-shift block, so that the two shift blocks arranged in the vertical direction do not have the same row index for “1” in any pair of corresponding columns. In FIG. 3, for example, while a column of the shift block S⁺¹ has a row index of 2, as indicated by reference numeral 301, the same column of the shift block S⁻¹ has a row index of 4, as indicated by reference numeral 302. Likewise, while a column of the shift block S⁺³ has a row index of 2, as indicated by reference numeral 303, the same column of the shift block S⁻³ has a row index of 3, as indicated by reference numeral 304. From the example, it can be seen that row indexes for “1” in corresponding columns of two shift blocks symmetrically arranged vertically are different.

In addition, in the parity check matrix according to an embodiment of the present invention, the p-th positive- or negative-shift block has a (p+N)-th positive- or negative-shift block on the left or right, where N is any integer, so that the two shift blocks when arranged horizontally side-by-side do not have the same column index for “1” in any pair of corresponding rows. In FIG. 3, for example, while a row of the shift block S⁺¹ has a column index of 3, as indicated by reference numeral 301, the same row of the shift block S⁺³ has a column index of 5, as indicated by reference numeral 303. Likewise, while a row of the shift block S⁻¹ has a column index of 2, as indicated by reference numeral 305, the same row of the shift block S⁻³ has a column index of 5, as indicated by reference numeral 304. From this example, it can be seen that column indexes for “1” in corresponding rows of two shift blocks symmetrically arranged horizontally are different.

As a consequence of the two features that two shift blocks arranged in the horizontal direction do not have the same row index for “1” in any pair of corresponding columns and two shift blocks arranged horizontally side-by-side do not have the same column index for “1” in any pair of corresponding rows, it is impossible for a rectangle having four corners which are all “1”s to be generated in the parity check matrix. At least one of the 4 corners necessarily must be a “0”. Thus, the cycle-4 phenomenon cannot occur in decoding the parity check matrix according to aspects of the present invention.

In another case where 2 “1”s are chosen as two corners of a rectangle in a sub-block, no other “1”s can be found in the shift block as two other corners for the rectangle, since any “1” in the shift block is unique in both row and column directions. Therefore, no rectangle having four corners which are all “1”s exists in the shift block.

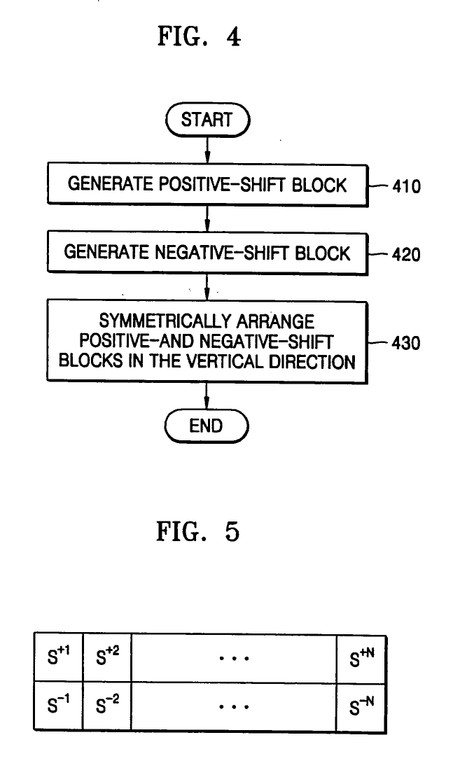

FIG. 4 is a flowchart illustrating a method of constructing a parity check matrix according to the embodiment of FIG. 2. In operation 410, by shifting all elements of an identity matrix p times to the right, a p-th positive-shift block is generated. In operation 420, by shifting all elements of an identity matrix p times to the left, a p-th negative-shift block is generated.

In operation 430, a low-density parity check matrix is generated by symmetrically arranging the p-th positive-shift block and the p-th negative shift block vertically. Here, if the p-th positive-shift block is placed on the upper part, other remaining positive-shift blocks should be arranged on the same upper part, and if the p-th negative-shift block is arranged on the upper part, other remaining negative-shift blocks should be arranged on the same upper part.

In a modified embodiment, shift blocks are arranged in order of shift number p. In this case, memory space can be further reduced. A more detailed description of such an embodiment will now be given with reference to FIG. 5.

FIG. 5 shows a parity check matrix generated by a second embodiment of the present invention. Referring to FIG. 5, the parity check matrix has the feature that shift blocks are regularly arranged by their shift numbers. That is, shift blocks are arranged in order of increasing shift number from left to right, such that S⁺¹, S⁺², S⁺³, etc. Thus, since it is only necessary to store N, the total number of shift block of the parity check matrix, a memory space required to store the parity check matrix may be further reduced. In FIG. 5, positive-shift blocks are placed on the upper part; however, the positions may be reversed.

In the following embodiments, shift blocks are arranged in order of increasing/decreasing shift number. However, in alternative embodiments, shift blocks may be randomly arranged as long as no shift number is repeated in the horizontal direction.

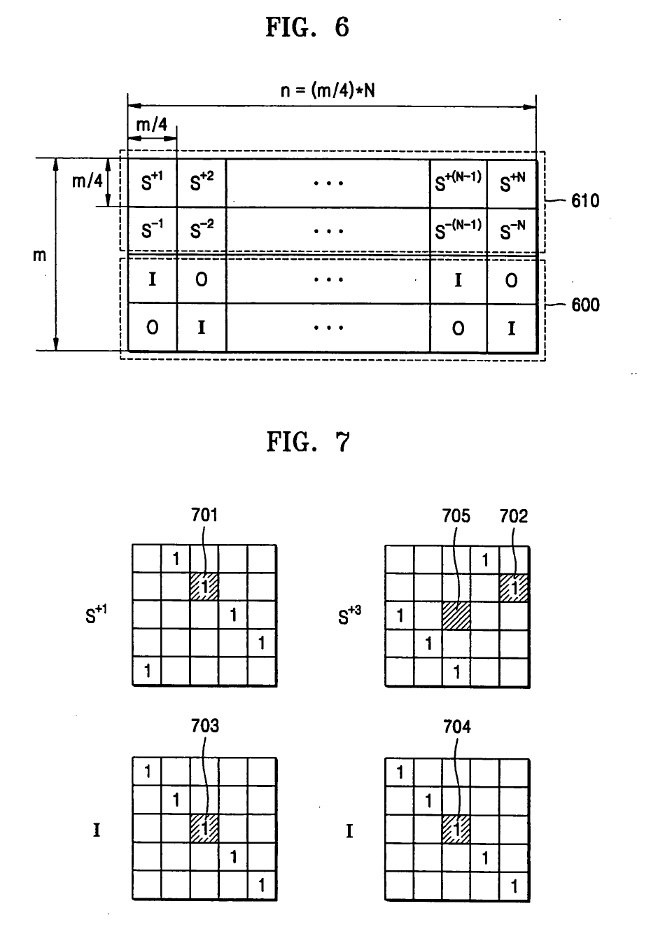

FIG. 6 shows a parity check matrix generated according to a third embodiment of the present invention. Referring to FIG. 6, the parity check matrix is generated by supplementing the parity check matrix of FIG. 2 with a lower sub-matrix 600 having the same dimensions as the parity matrix of FIG. 2. The lower sub-matrix 600 is composed of one or more identity matrices Is and zero matrices 0s, each having the same dimensions as the shift block of the upper sub-matrix 610. The identity matrices Is and zero matrices 0s are alternately arranged in vertical and horizontal directions. Row weight of the parity check matrix of FIG. 6 is 3. However, column weight is not constant.

FIG. 7 shows matrices for explaining how the cycle-4 phenomenon can be prevented with the parity check matrix of FIG. 6. First, a case where two corners are chosen in the upper sub-matrix 610 and then two remaining corners are chosen in the lower sub-matrix 600 will be considered. Here, the corners belong to a rectangle having corner positions which are associated with the cycle-4 phenomenon.

In the same way as shown in FIG. 2, the parity check matrix of FIG. 6 has a p-th positive- or negative-shift block and a (p+N)-th positive- or negative-shift block on the same upper part in the horizontal direction, and no two “1”s in the same row of the two shift blocks have the same column index. For example, while a row in the shift block S⁺¹ has a column index of 3, as indicated by reference numeral 701, the same row in the shift block S⁺³ has a column index of 5, as indicated by reference numeral 702. That is, column indexes for “1”s in the same row in S⁺¹ and S⁺³ are different.

In the horizontal direction of shift blocks in the lower sub-matrix 600, since the shift blocks are identity matrices and zero matrices, it is possible for two “1”s in the same row of the two shift blocks to have the same column index in the lower sub-matrix 600. However, as described above, since no two “1”s in the same row of the two sub-shift blocks have the same column index in sub-shift blocks on the upper sub-matrix 610 in the horizontal direction, even if two “1”s in the same row have the same column index in the lower sub-matrix 600, at least one of their matches corresponding to remaining corners of a rectangle is not “1”, thereby avoiding the cycle-4 phenomenon. For example, in FIG. 7, there are a row in the identity matrix on the left having a column index of 3, as indicated by reference numeral 703, and the same row in the identity matrix on the right having a column index of 3, as indicated by reference numeral 704. There is a column index of 3, as indicated by the reference numeral 701 in the shift block S⁺¹, matching with the column index 703, but there is no same column index in the same row in the sub-shift matrix S⁺³ as that of S⁺¹ matching with the column index 704, which cannot complete a rectangle, thereby avoiding the cycle-4 phenomenon.

In another case where all four “1”s are chosen as four corners of a rectangle in the upper sub-matrix 610 or the lower sub-matrix 600, since every “1” in an identity matrix and hence a shift block matrix is unique in row and column direction, no rectangle having four corners which are all “1”s can exist.

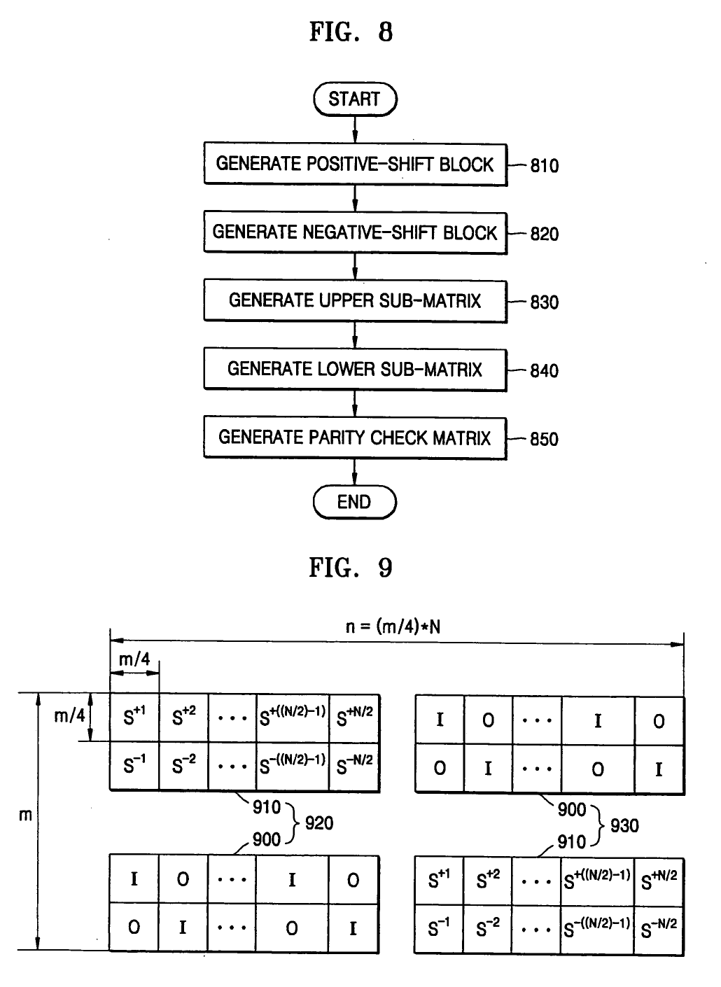

FIG. 8 is a flowchart illustrating a method of constructing the parity check matrix of FIG. 6. In operation 810, by shifting all elements of an identity matrix p times to the right, a p-th positive-shift block is generated. In operation 820, by shifting all elements of an identity matrix p times to the left, a p-th negative-shift block is generated. In operation 830, an upper sub-matrix 610 is generated by symmetrically arranging the p-th positive- and negative-shift blocks in the vertical direction.

In operation 840, a lower sub-matrix 600 is generated by alternately arranging unit matrices I's and zero matrices 0's in both the vertical and horizontal directions, each identity matrix and zero matrix having the same size as the shift block of the upper sub-matrix 610. In operation 850, a parity check matrix is generated by placing the upper sub-matrix 610 directly above or directly below the lower sub-matrix 600.

FIG. 9 shows a parity check matrix generated by a fourth embodiment of the present invention. First, the parity check matrix is a regular parity check matrix that has constant column and row weight. Second, column weight is 3, and row weight is N/2+(N/2×½)=3N/4. Here, N is the sum of the number of shift blocks in the horizontal direction, the number of identity matrices, and the number of zero matrices.

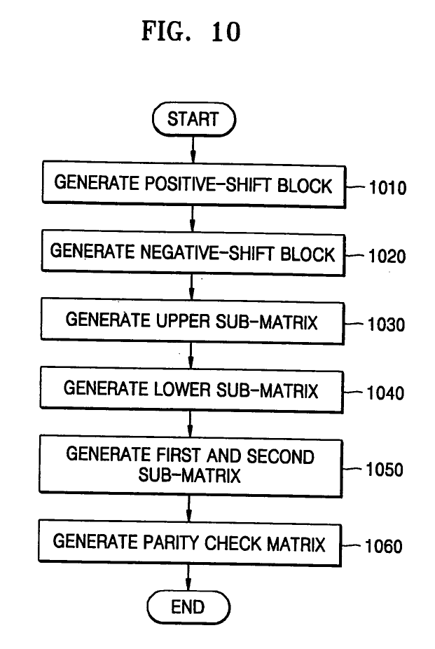

FIG. 10 is a flowchart that illustrates a method of constructing the parity check matrix of FIG. 9. In operation 1010, a p-th positive-shift block is generated by shifting all elements of an identity matrix p times to the right. In operation 1020, a p-th negative-shift block is generated by shifting all elements of an identity matrix p times to the left. In operation 1030, an upper sub-matrix 910 is generated by symmetrically arranging the p-the positive- and negative-shift blocks in the vertical direction.

In operation 1040, a lower sub-matrix 900 is generated by alternately arranging unit matrices I's and zero matrices O's in both vertical and horizontal directions, each identity matrix and zero matrix having the same dimensions as the shift block of the upper sub-matrix 910. In operation 1050, a first sub-matrix 920 is generated by placing the upper sub-matrix 910 directly above the lower sub-matrix 900, and a second sub-matrix 930 is generated by placing the upper sub matrix 910 directly below the lower sub-matrix 910. In operation 1060, a parity check matrix is generated by arranging the second sub matrix 910 on the left or right of the first sub matrix 900.

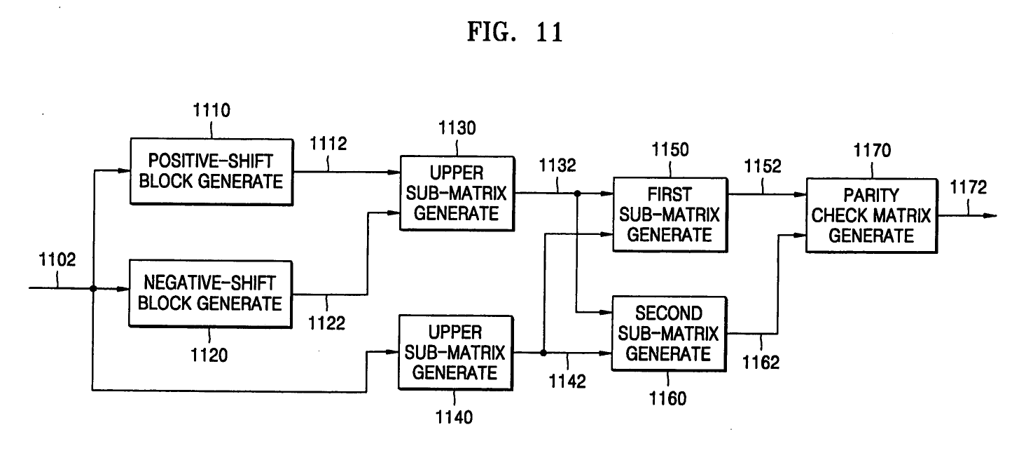

FIG. 11 is a block diagram of an apparatus for constructing a parity check matrix, according to the present invention. Although a few embodiments of the present invention have been shown and described, it would be appreciated by those skilled in the art that changes may be made in these embodiment without departing from the principles and spirit of the invention, the scope of which is defined in the claims and their equivalents. The apparatus includes a positive-shift block generator 1110, a negative-shift block generator 1120, an upper sub-matrix generator 1130, a lower sub-matrix generator 1140, a first sub-matrix generator 1150, a second sub-matrix generator 1160, and a parity check matrix generator 1170.

The positive-shift block generator 1110 generates a p-th positive shift block 1112 by shifting all elements of an identity matrix 1102p times to the right. The negative-shift block generator 1120 generates a p-th negative shift block 1122 by shifting all elements of the unit matrix 1102p times to the left.

The upper sub-matrix generator 1130 generates an upper sub-matrix 1132 by symmetrically arranging the p-th positive- and negative-shift blocks 1112 and 1122 in the vertical direction, such that the p-th positive-shift block 1112 is placed on the upper part (or lower part), while the p-th negative-shift block 1122 is placed on the lower part (or upper part).

The upper sub-matrix 1132 may be used as an independent parity check matrix. In that case, the upper sub-matrix generator 1130 generates the upper sub-matrix 1132 by arranging positive- or negative-shift blocks 1112 or 1122 in the horizontal direction in order of shift number, thus enabling further reduction of memory space required to store the parity check matrix.

The lower sub-matrix generator 1140 generates a lower sub-matrix 1142 by alternately arranging identity matrices 1102 and zero matrices in both vertical and horizontal directions, the each identity matrix and zero matrix having the same dimensions as the shift block of the upper sub-matrix 1132.

The first sub-matrix generator 1150 generates a first sub-matrix 1152 by arranging the upper sub-matrix 1132 and the lower sub-matrix 1142 in the vertical direction such that the upper sub-matrix 1132 is placed on the upper part and the lower sub-matrix 1142 is placed on the lower part.

The second sub-matrix generator 1160 generates a second sub-matrix 1162 by arranging the upper sub-matrix 1132 and the lower sub-matrix 1142 in the vertical direction such that the lower sub-matrix 1142 is placed on the upper part and the upper sub-matrix 1132 is placed on the lower part. The first or the second sub-matrix itself can be used as a parity check matrix. The parity check matrix generator 1170 generates a regular parity check matrix 1172 by horizontally arranging the first sub-matrix 1152 and the second sub-matrix 1162.

As described above, according to aspects of the present invention, it is possible to easily construct the parity check matrix and avoid the cycle-4 phenomenon. Also, memory space required to store the parity check matrix can be significantly reduced.

The above-described method of constructing a parity check matrix according to aspects of the present invention may be implemented as a computer program. Codes and code segments constituting the computer program may readily be inferred by those skilled in the art. The computer programs may be recorded on computer-readable media and read and executed by a computer. Such computer-readable media include all kinds of storage devices, such as ROM, RAM, CD-ROM, magnetic tape, floppy discs, optical data storage devices, etc., and may be realized in the form of carrier waves, e.g., transmission over the Internet. The computer-readable media may be distributed among computer systems connected to a network, and codes on the distributed computer-readable media may be stored and executed in a decentralized fashion.

Although a few embodiments of the present invention have been shown and described, it would be appreciated by those skilled in the art that changes may be made in these embodiment without departing from the principles and spirit of the invention, the scope of which is defined in the claims and their equivalents.

What is claimed is:

1. A method of constructing a low-density parity check matrix, the method comprising:
generating a p-th positive-shift block by shifting all elements of an identity matrix p times to the right;
generating a p-th negative-shift block by shifting all elements of the identity matrix p times to the left; and
horizontally arranging one or more pairs of different p-th positive- and negative-shift blocks symmetrically arranged in the vertical direction.

2. The method of claim 1, wherein the horizontally arranging of the one or more pairs of p-th positive- and negative-shift blocks comprises:
placing the p-th negative-shift block directly above or directly below the p-th positive-shift block.

3. The method of claim 1, wherein the horizontally arranging of the one or more pairs of p-th positive- and negative-shift blocks comprises:
sequentially arranging the positive- and negative-shift blocks according to shift numbers of the positive- and negative-shift blocks.

4. The method of claim 1, further comprising:
alternately arranging identity matrices and zero matrices, directly above or directly below an upper sub-matrix resulting from symmetrically arranging the positive- and negative-shift blocks in the vertical direction.

5. The method of claim 4, wherein the alternately arranging of the identity matrices and the zero matrices directly above or directly below an upper sub-matrix comprises:
generating a lower sub-matrix by alternately arranging the identity and zero matrices in both vertical and horizontal directions, where the identity and zero matrices have the same dimensions as the positive- and negative-shift blocks; and
placing the lower sub-matrix directly above or directly below the upper sub-matrix.

6. The method of claim 1, further comprising:
generating a regular parity check matrix by alternately arranging the upper sub-matrices and lower sub-matrices.

7. The method of claim 6, wherein the generating of the regular parity check matrix comprises:
generating a first sub matrix by placing the lower sub-matrix directly below the upper sub-matrix;
generating a second sub matrix by placing the upper sub-matrix directly below the lower sub-matrix; and
placing the second sub matrix on the left or right of the first sub matrix.

8. An apparatus for constructing a low-density parity check matrix, the apparatus comprising:
a positive-shift block generator that generates a p-th positive-shift block by shifting all elements of an identity matrix p times to the right;
a negative-shift block generator that generates a p-th negative-shift block by shifting all elements of the unit matrix p times to the left; and
an upper sub-matrix generator that generates an upper sub-matrix by horizontally arranging one or more pairs of different p-th positive- and negative-shift blocks symmetrically arranged in the vertical direction.

9. The apparatus of claim 8, wherein the upper sub-matrix generator generates the upper sub-matrix by placing the p-th negative-shift block directly above or directly below the p-th positive-shift block.

10. The apparatus of claim 8, wherein the upper sub-matrix generator generates the upper sub-matrix by sequentially arranging positive- and negative-shift blocks according to shift numbers of the positive- and negative-shift blocks.

11. The apparatus of claim 8, further comprising:
a lower sub-matrix generator that generates a lower sub-matrix by alternately arranging identity matrices and zero matrices, each having the same dimensions as the positive- and negative-shift blocks, and a lower sub-matrix having the same dimensions of the upper sub-matrix; and
a first sub-matrix generator that generates a first sub-matrix by placing the lower sub-matrix directly below the upper sub-matrix.

12. The apparatus of claim 11, further comprising:
a second sub-matrix generator that generates a second sub-matrix by placing the lower sub-matrix directly above the upper sub-matrix;
a parity check matrix generator that generates a regular parity check matrix by symmetrically arranging the first sub-matrix and the second sub-matrix in the horizontal direction.

13. A computer-readable recording medium storing a program for a computer to execute a method of constructing a low-density parity check matrix, the method comprising:
generating a p-th positive-shift block by shifting all elements of an identity matrix p times to the right;
generating a p-th negative-shift block by shifting all elements of the identity matrix p times to the left; and
horizontally arranging one or more pairs of different p-th positive- and negative-shift blocks symmetrically arranged in the vertical direction.

14. The recording medium of claim 13, wherein the horizontally arranging of the one or more pairs of p-th positive- and negative-shift blocks comprises:
placing the p-th negative-shift block directly above or directly below the p-th positive-shift block.

15. The recording medium of claim 13, wherein the horizontally arranging of the one or more pairs of p-th positive- and negative-shift blocks comprises:
sequentially arranging the positive- and negative-shift blocks according to shift numbers of the positive- and negative-shift blocks.

16. The recording medium of claim 13, wherein the method further comprises:
alternately arranging identity matrices and zero matrices, directly above or directly below an upper sub-matrix resulting from symmetrically arranging the positive- and negative-shift blocks in the vertical direction.

17. The recording medium of claim 16, wherein the alternately arranging of the identity matrices and the zero matrices directly above or directly below an upper sub-matrix comprises:
generating a lower sub-matrix by alternately arranging the identity and zero matrices in both vertical and horizontal directions, where the identity and zero matrices have the same dimensions as the positive- and negative-shift blocks; and
placing the lower sub-matrix directly above or directly below the upper sub-matrix.

18. The recording medium of claim 13, wherein the method further comprises:
generating a regular parity check matrix by alternately arranging the upper sub-matrices and lower sub-matrices.

19. The recording medium of claim 18, wherein the generating of the regular parity check matrix comprises:
generating a first sub matrix by placing the lower sub-matrix directly below the upper sub-matrix;
generating a second sub matrix by placing the upper sub-matrix directly below the lower sub-matrix; and
placing the second sub matrix on the left or right of the first sub matrix.

20. The method of claim 1, wherein:
no two p-th positive or p-th negative shift blocks appear in the horizontal direction.

21. The method of claim 1, wherein:
where a pair of p-th positive and p-th negative shift blocks are symmetrically arranged in the vertical direction, the p-th positive and the p-th negative shift blocks of the pair do not have a same row index for “1” in any pair of corresponding columns.

22. The method of claim 1, wherein the horizontally arranging of the one or more pairs of p-th positive- and negative-shift blocks comprises:
randomly arranging the positive- and negative-shift blocks wherein no shift number is repeated in the horizontal direction.

23. The method of claim 5, wherein:
each of the upper sub-matrix and the lower sub-matrix comprises a plurality of sub-shift blocks;
no two 1's in a same row of two-sub-shift blocks of the upper sub-matrix have a same column index; and
two 1's in a same row of two sub-shift blocks of the lower sub-matrix have a same column index.
